(19) United States
(12) Patent Application Publication
(10) Pub. No.: US 2026/0104737 A1
(43) Pub. Date: Apr. 16, 2026

(54) FOLDABLE DISPLAY DEVICE

(71) Applicant: LG Display Co., Ltd., Seoul (KR)

(72) Inventors: Hyeonggwang AN, Paju-si (KR); JiSoon OH, Paju-si (KR); Sangmin WOO, Paju-si (KR); Jaewoo LEE, Paju-si (KR); Jongseok CHA, Paju-si (KR); ShinSuk LEE, Paju-si (KR); Namseok LEE, Paju-si (KR)

(73) Assignee: LG Display Co., Ltd., Seoul (KR)

(21) Appl. No.: 19/259,783

(22) Filed: Jul. 3, 2025

(30) Foreign Application Priority Data
Oct. 16, 2024 (KR) 10-2024-0140897

(51) Int. Cl. G06F 1/16; H10K 59/80; H10K 102/00

(52) U.S. Cl. CPC G06F 1/1652; H10K 59/8722; H10K 59/8793; H10K 2102/311

(57) ABSTRACT

A foldable display device includes a display panel including a folding area being bendable or foldable with respect to a folding axis and a non-folding area, a support layer disposed on a back surface of the display panel, a first adhesive layer disposed between the display panel and the support layer, a base substrate disposed on a back surface of the support layer and having an open pattern formed in an area overlapping with the folding area, and a second adhesive layer disposed between the support layer and the base substrate, the first adhesive layer having a modulus greater than the second adhesive layer.

### CROSS-REFERENCE TO RELATED APPLICATION

This application claims priority from Korean Patent Application No. 10-2024-0140897, filed on Oct. 16, 2024 in the Korean Intellectual Property Office, which is hereby incorporated by reference for all purposes as if fully set forth herein.

### BACKGROUND

### Technical Field

The present disclosure relates to electronic devices, and more specifically, to foldable display devices.

### Description of the Related Art

In today's information society, display devices for presenting images or visual information to users are increasingly important. The needs for such display devices has caused display technology to be rapidly developed, and various types or usages of display devices being thinner and lighter, consuming low power, and having excellent performance have been developed.

For example, a liquid crystal display (LCD) device, an organic light emitting diode display device, a plasma display device (PDP), a field emission display device (FED), an inorganic light emitting diode display device, a micro light emitting diode display device, a mini light emitting diode display device, a quantum dot light emitting diode display device, and the like, have been developed and become increasingly advanced.

Recently, demands for foldable display devices manufactured using flexible substrates there has increased. Foldable display devices can be carried in a folded state and display images in an unfolded state. Therefore, foldable display devices have advantages of being easy to carry and presenting images on a large screen. However, since folding and unfolding operations of the foldable display devices with respect to a folding axis are repeated too many to be counted, foldable display devices have suffered from wrinkles being visible due to stress applied to a folding area.

### BRIEF SUMMARY

To address this issue, one or more aspects of the present disclosure may provide a foldable display device that has a structure where a modulus of an adhesive layer disposed between a display panel and a support layer is set to 1 Mpa or higher, and is capable of reducing or improving wrinkles visible on the display panel and thereby improving appearance quality.

One or more aspects of the present disclosure may provide a foldable display device that has a structure where one or more grooves extending in a folding axis direction are patterned in an adhesive layer disposed between a display panel and a support layer, and is capable of improving folding performance.

According to one or more example embodiments of the present disclosure, a foldable display device can be provided that includes a display panel including a folding area being bendable or foldable with respect to a folding axis and a non-folding area, a support layer disposed on a back surface of the display panel, a first adhesive layer disposed between the display panel and the support layer, a base substrate disposed on a back surface of the support layer and having an open pattern formed in an area overlapping with the folding area, and a second adhesive layer disposed between the support layer and the base substrate. In one or more aspects, the first adhesive layer may have a modulus greater than the second adhesive layer.

According to one or more example embodiments of the present disclosure, a foldable display device can be provided that includes a display panel including a folding area being bendable or foldable with respect to a folding axis and a non-folding area, a support layer disposed on a back surface of the display panel, a first adhesive layer disposed between the display panel and the support layer, a base substrate disposed on a back surface of the support layer and having an open pattern formed in an area overlapping with the folding area, and a second adhesive layer disposed between the support layer and the base substrate. In one or more aspects, the first adhesive layer may have a modulus greater than the second adhesive layer, and a plurality of grooves extending in a folding axis direction are patterned on one side of the first adhesive layer facing the display panel,

According to one or more aspects of the present disclosure, a foldable display device may be provided that is capable of reducing or improving wrinkles visible on a display panel and thereby improving appearance quality by including a structure where a modulus of an adhesive layer disposed between the display panel and a support layer is set to 1 Mpa or higher.

According to one or more aspects of the present disclosure, a foldable display device may be provided that is capable of improving folding performance by including a structure where one or more grooves extending in a folding axis direction are patterned in an adhesive layer disposed between a display panel and a support layer.

According to one or more aspects of the present disclosure, a foldable display device may be provided that is capable of being driven at low power by including light emitting elements implemented as organic light emitting diodes (OLED).

### BRIEF DESCRIPTION OF THE SEVERAL VIEWS OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 is a plan view of an example foldable display device according to aspects of the present disclosure;

FIG. 2 is an example cross-sectional view taken along line A-A′ of the foldable display device shown in FIG. 1;

FIG. 3 is a plan view of an example first adhesive layer according to aspects of the present disclosure;

FIG. 4 is an example cross-sectional view taken along line B-B′ of the foldable display device shown in FIG. 1;

FIG. 5 illustrates a change of a wrinkle of a foldable display device including the first adhesive layer having a modulus of 0.05 Mpa; and

FIG. 6 illustrates a change of a wrinkle of a foldable display device including the first adhesive layer having a modulus of 1 Mpa.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the claims and their equivalents are not limited by the disclosure. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

Hereinafter, with reference to the accompanying drawings, various embodiments of the present disclosure will be described in detail. Unless otherwise noted below, the term “modulus” refers to the modulus of elasticity.

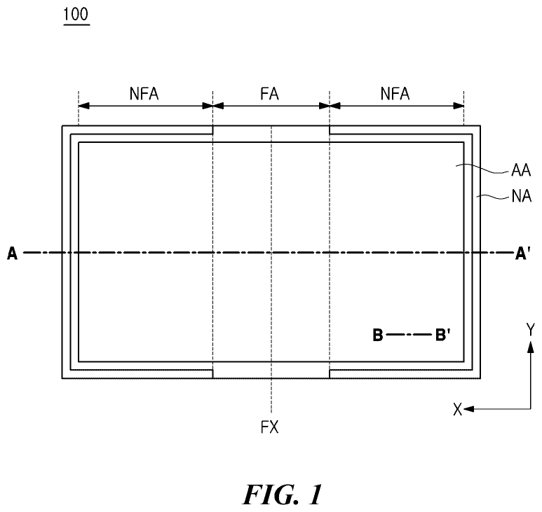

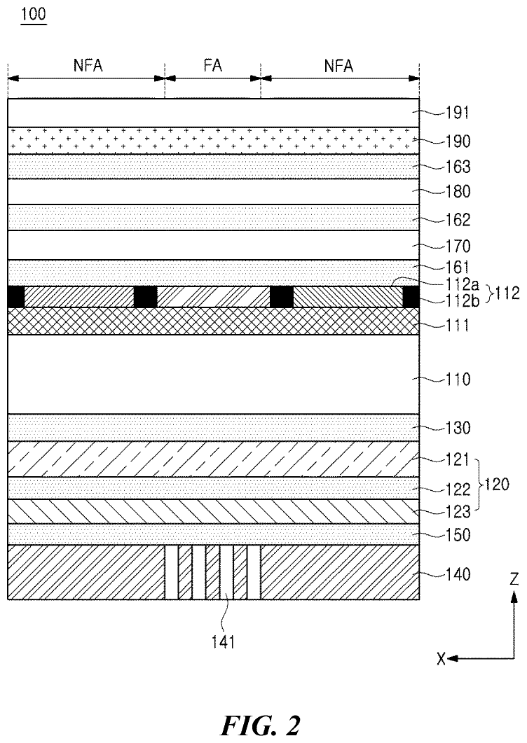

FIG. 1 is a plan view of an example foldable display device 100 according to aspects of the present disclosure. FIG. 2 is a cross-sectional view taken along line A-A′ of the foldable display device 100 shown in FIG. 1.

Referring to FIGS. 1 and 2, in one or more example embodiments, the foldable display device 100 may include a display panel 110, a support layer 120, a first adhesive layer 130, a base substrate 140, and a second adhesive layer 150.

Hereinafter, for convenience of description and ease of the understanding, discussions are provided based on a configuration that a display surface of the display panel 110 on which images are presented faces the front of the foldable display device 100, and the support layer 120, the first adhesive layer 130, the base substrate 140, and the second adhesive layer 150 are located on the back surface of, or under, the display panel 110 in the cross-sectional view.

The display panel 110 may be a panel on which images are presented. Light emitting elements for presenting images, and circuits, lines, and components for driving the light emitting elements may be arranged in the display panel 110. For example, the display panel 110 may be applied to one selected from a liquid crystal display (LCD) device, a field emission display (FED) device, an electroluminescence display (ELD) device, an organic light emitting diode (OLED) display device, an inorganic light emitting diode display device, a quantum dot light emitting diode display device, a micro light emitting diode display device, a mini light emitting diode displays device, or the like. In one or more aspects, as representative light emitting elements, organic light emitting diodes (OLED) may be applied to a flexible display device capable of maintaining display performance even when being bent like paper.

Organic light emitting diodes (OLED) are self-emissive light emitting elements, and since backlight used for non-self-emissive liquid crystals is not required, display devices implemented using the OLEDs can be made lighter and thinner. Further, when compared to LCD devices, OLED display devices have an wide viewing angle, excellent contrast ratio, low power consumption, fast response speed, and the like, and provide advantages of being driven by a low DC voltage, being resistant to external impact because internal components are configured in a solid structure, and having a wide operating temperature range. Further, since the manufacturing process is simple, OLED display devices have an advantage of being able to reduce the production cost significantly compared to LCD devices.

The display panel 110 may include a display area AA where an image is displayed and a non-display area NA where an image is not displayed. The non-display area NA may be an area outside of the display area AA, and be referred to as a non-active area or a bezel area. All or a portion of the non-display area NA may be an area visible in front of the foldable display device 100, or may be an area that is bent and not visible in front of the foldable display device 100.

The display panel 110 may include a folding area FA and a non-folding area NFA.

The folding area FA is an area in which the foldable display device 100 can be bent or folded. For example, the folding area FA may be bent or folded with respect to a folding axis FX, and may be bent or folded within a specific radius of curvature.

FIG. 1 illustrates that the folding axis FX is arranged in a Y-axis direction at the center of the display panel 110, but aspects of the present disclosure are not limited thereto. For example, the folding axis FX may be arranged in a X-axis direction at the center of the display panel 110. In one or more aspects, multiple folding axes FX may be defined and be arranged spaced apart from each other in the X-axis direction or the Y-axis direction.

The non-folding areas NFA may be areas where the display panel 110 is not folded and the display panel 110 remains in a flat state. For example, the non-folding areas NFA may extend to both sides of the folding area FA, and two non-folding areas NFA may be disposed with the folding area FA in therebetween.

When the foldable display device 100 is in an unfolded state, the folding area FA and the non-folding area NFA may form a one plane. When the foldable display device 100 is in a folded state with respect to the folding axis FX, the non-folding areas NFA on both sides of the folding area FA may be arranged to face each other while maintaining a flat state.

The support layer 120 may be disposed on the back surface of the display panel 110. According to this configuration, since the support layer 120 is disposed on the back surface of the display panel 110, the strength of the display panel 110 with a thin thickness can be improved. For example, the support layer 120 may be in the form of one or more layers, and may include a polymer material such as polymethylmethacrylate (PMMA), polycarbonate (PC), polyvinylalcohol (PVA), acrylonitrile-butadiene-styrene (ABS), polyethylene terephthalate (PET), silicone, polyurethane (PU), or the like.

The first adhesive layer 130 may be disposed between the display panel 110 and the support layer 120. For example, the first adhesive layer 130 may be located between the display panel 110 and the support layer 120 and can serve to adhere the display panel 110 and the support layer 120.

The first adhesive layer 130 may include a pressure sensitive adhesive (PSA) or an optical clear adhesive (OCA). In an example where the foldable display device 100 is configured with a top-emission structure, the first adhesive layer 130 disposed under the display panel 110 may include either the pressure sensitive adhesive (PSA) or the optical clear adhesive (OCA). In another example where the foldable display device 100 is configured with a bottom-emission structure, the first adhesive layer 130 may include the optical clear adhesive (OCA). This is because the optical clear adhesive (OCA) has better light transmittance than the pressure sensitive adhesive (PSA). For example, the optical clear adhesive (OCA) can be formed to transmit light by 97% or more.

The base substrate 140 may be disposed on the back surface of the support layer 120. For example, the base substrate 140 may include a metal material such as stainless steel (SUS), or a polymer material such as polymethyl methacrylate (PMMA), polycarbonate (PC), polyacrylate (PA), polyvinyl alcohol (PVA), acrylonitrile-butadiene-styrene (ABS), polyethylene terephthalate (PET), or the like.

In an example where the base substrate 140 include a high-rigidity material such as stainless steel (SUS), the base substrate 140 may have a high restoring force, and therefore, a thickness of the base substrate 140 can be reduced. Further, even when the thickness of the base substrate 140 is reduced, since the base substrate 140 can be provided with desired rigidity, therefore, the base substrate 140 can serve as a support for the display panel 110.

However, since a high-rigidity material such as stainless steel (SUS) has a narrow elastic deformation region, it may be difficult to restore after deformation. For example, the base substrate 140 including a high-rigidity material such as stainless steel (SUS) may not be unfolded immediately when changed to the unfolded state after folding, and a time taken to maintain the shape in the folding state may increase as the display device 100 is used.

To address this issue, the base substrate 140 may have an open pattern 141 formed in an area overlapping with the folding area FA. For example, a restoring force for the folding area FA of the base substrate 140 can be improved through the open pattern 141.

The second adhesive layer 150 may be disposed between the support layer 120 and the base substrate 140. For example, the second adhesive layer 150 may be used to adhere between the support layer 120 and the base substrate 140.

The second adhesive layer 150 may be formed to have a low modulus of 0.02 to 0.07 MPa at room temperature (20±5° C.). This is because the lower the modulus, the higher the flexibility is and the better the bendability is. Therefore, due to the low modulus of the second adhesive layer 150, the foldable display device 100 can provide an advantage of easily performing folding operation.

The second adhesive layer 150 may include a pressure sensitive adhesive (PSA) or an optical clear adhesive (OCA). In an example where the foldable display device 100 is configured with a top-emission structure, the second adhesive layer 150 disposed under the display panel 110 may include either the pressure sensitive adhesive (PSA) or the optical clear adhesive (OCA). In another example where the foldable display device 100 is configured with a bottom-emission structure, the second adhesive layer 150 may include the optical clear adhesive (OCA). This is because the optical clear adhesive (OCA) has better light transmittance than the pressure sensitive adhesive (PSA).

In one or more aspects, the first adhesive layer 130 may be formed to have a modulus greater than that of the second adhesive layer 150. For example, the first adhesive layer 130 may be formed to have a modulus about 40 to 60 times as great as that of the second adhesive layer 150 at room temperature. For example, the first adhesive layer 130 may be formed to have a modulus of 1 MPa or more at room temperature.

According to these configurations, since the first adhesive layer 130 disposed on the back surface of the display panel 110 is formed to have a large modulus of 1 MPa or more, the restoring force of the first adhesive layer 130 can be improved. For example, wrinkles visible on the display panel 110 can be prevented by implementing a characteristic of maintaining a flat surface in the unfolded state. When the first adhesive layer 130 has the same modulus as the second adhesive layer 150, the flexibility of the first adhesive layer 130 may increase, but the restoring force thereof may be reduced, and therefore, wrinkles in the folded state may remain in the folding area FA and be visible on the display panel 110. In contrast, when the first adhesive layer 130 is formed to have a high modulus of 1 Mpa or more, the restoring force can increase when changed from folding to unfolding, and therefore, wrinkles occurring in the folding area FA can be prevented or reduced. Therefore, since wrinkles are invisible on the display panel 110, the appearance quality can be improved.

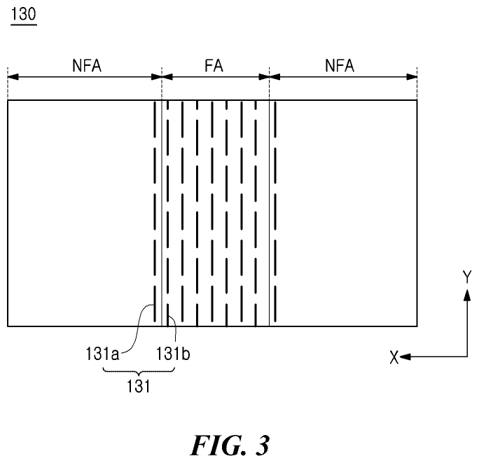

FIG. 3 is an example plan view of the first adhesive layer 130 according to aspects of the present disclosure.

Referring to FIG. 3, the first adhesive layer 130 may include a plurality of grooves 131 patterned on one surface facing the display panel 110. This is because, when the first adhesive layer 130 has a high modulus of 1 Mpa or more, flexibility may be reduced, which may adversely affect folding performance. To address this issue, the grooves 131 may be formed to extend in the direction of the folding axis FX on one surface of the first adhesive layer 130, and thereby, folding performance can be improved.

The grooves 131 may be disposed to overlap with the folding area FA. For example, the grooves 131 may be disposed in the folding area FA and a portion of the non-folding area NFA adjacent to the folding area FA. According to this configuration, as the grooves 131 are formed even in the non-folding area NFA adjacent to the folding area FA, the folding performance can be further improved.

The grooves 131 may be formed by laser processing. For example, the grooves 131 may have a width of 10 to 30 μm in a direction perpendicular to the folding axis FX, which is the X-axis direction in FIG. 3, and a length of 5 to 20 mm in the folding axis FX direction, which is the Y-axis direction. For example, the grooves 131 may be spaced apart from each other by a distance of 5 to 20 mm in the X-axis direction and by a distance of 3 to 10 mm in the Y-axis direction. The shape of the grooves 131 according to aspects of the present disclosure is not limited thereto. For example, the shape of the grooves 131 may be changed based on the size and structure of the foldable display device 100.

The grooves 131 may include a first pattern 131a and a second pattern 131b.

The first pattern 131a may be formed to extend in the direction of the folding axis FX, and be in the form of a plurality of first patterns 131a. For example, the plurality of first patterns 131a may be disposed to be spaced apart from each other in the direction of the folding axis FX, and form a first pattern line in the Y-axis direction.

The second pattern 131b may be formed to extend in the direction of the folding axis FX, and be in the form of a plurality of second patterns 131b. For example, the plurality of second patterns 131b may be disposed to be spaced apart from each other in the direction of the folding axis FX, and form a second pattern line in the Y-axis direction. In one or more aspects, the second patterns 131b may be disposed spaced apart from the first patterns 131a in a direction perpendicular to the folding axis FX, and therefore, the second pattern line may be disposed to be spaced apart from the first pattern line in the X-axis direction.

The plurality of first patterns 131a and the plurality of second patterns 131b may be disposed in a plurality of lines in the direction perpendicular to the folding axis FX. For example, the first patterns 131a and the second patterns 131b may be spaced apart from each other in the X-axis direction. For example, the first patterns 131a may be disposed in odd-numbered lines in the X-axis direction, and the second patterns 131b may be disposed in even-numbered lines. In one or more aspects, both ends of each second pattern 131b and both ends of each first pattern 131a may be disposed in a staggered pattern. That is, both ends of each second pattern 131b may be disposed not to align with both ends of each first pattern 131a. Thereby, flexibility can be provided to the whole area of the folding area FA.

In one or more aspects, the support layer 120 may include a first support layer 121, an intermediate adhesive layer 122, and a second support layer 123.

The first support layer 121 may be disposed on the back surface of the first adhesive layer 130 to support the display panel 110.

The intermediate adhesive layer 122 may be disposed on the back surface of the first support layer 121 to be used to adhere the first support layer 121 and the second support layer 123. For example, the intermediate adhesive layer 122 may be formed to have a low modulus of 0.02 to 0.07 MPa, similar to the second adhesive layer 150.

The second support layer 123 may be disposed on the back surface of the intermediate adhesive layer 122. For example, the second support layer 123 may be disposed between the intermediate adhesive layer 122 and the second adhesive layer 150, and can prevent the open pattern 141 formed in the base substrate 140 from being visible on the display panel 110. For example, due to the low modulus of the second adhesive layer 150, the opening pattern 141 of the base substrate 140 may be transferred to the second adhesive layer 150 and thereby be visible on the display panel 110, but since the second support layer 123 is disposed between the display panel 110 and the second adhesive layer 150, the open pattern 141 can be prevented from being visible on the display panel 110.

In one or more aspects, in a structure where the open pattern 141 can be prevented from being visible on the display panel 110 only by the first support layer 121, only the first support layer 121 may be disposed on the base substrate 140 without the second support layer 123. In this configuration, the intermediate adhesive layer 122 and the second support layer 123 may be omitted.

The foldable display device 100 may further include at least one additional adhesive layer for attaching additional layers of the foldable display device. For example, the foldable display device 100 may further a third adhesive layer 161, a polarizing plate 170, a fourth adhesive layer 162, a cover glass 180, a fifth adhesive layer 163, and a protection layer 190. The first adhesive layer may have a modulus greater than the at least one additional adhesive layer either. As an example, the modulus of the second adhesive layer and that of the at least one additional adhesive layer can be of the same magnitude.

The third adhesive layer 161 may be disposed on the display panel 110. For example, the third adhesive layer 161 may be formed to have a low modulus of 0.02 to 0.07 MPa to ensure flexibility. Since the third adhesive layer 161 is located on the display panel 110, i.e., on the display surface, it may be desired to apply an optical clear adhesive (OCA) having good light transmittance.

The polarizing plate 170 may be disposed on the third adhesive layer 161. For example, the polarizing plate 170 may be attached to the display panel 110 by the third adhesive layer 161. The polarizing plate 170 can selectively transmit light to reduce reflection of external light incident on the display panel 110. For example, the polarizing plate 170 may include a material such as polyvinyl alcohol (PVA), polycarbonate (PC), polymethacrylate (PMMA), or the like.

The fourth adhesive layer 162 may be disposed on the polarizing plate 170. For example, the fourth adhesive layer 162 may be formed to have a low modulus of 0.02 to 0.07 MPa to ensure flexibility. Since the fourth adhesive layer 162 is located over the display panel 110, i.e., over the display surface, it may be desired to apply an optical clear adhesive (OCA) having good light transmittance.

The cover glass 180 may be disposed on the fourth adhesive layer 162. For example, the cover glass 180 may be disposed over the polarizing plate 170 with the fourth adhesive layer 162 interposed therebetween. The cover glass 180 may be intended to protect the display panel 110, and may be formed of a glass material having excellent optical properties, high strength and impact resistance, and excellent surface hardness. For example, the cover glass 180 may be a thin cover glass (TCG) having a thickness of 90 μm or less. The thin cover glass 180 having such a limited thickness can effectively relieve or reduce stress applied when the display device is folded or bent.

The fifth adhesive layer 163 may be disposed on the cover glass 180. For example, the fifth adhesive layer 163 may be formed to have a low modulus of 0.02 to 0.07 MPa to ensure flexibility. Since the fifth adhesive layer 163 is located over the display panel 110, i.e., over the display surface, it may be desired to apply an optical clear adhesive (OCA) having good light transmittance.

The protection layer 190 may be disposed on the fifth adhesive layer 163. For example, the protection layer 190 may be disposed over the cover glass 180 with the fifth adhesive layer 163 interposed therebetween. Since the protection layer 190 is disposed over the cover glass 180, the cover glass 180 can be protected from compressive stress and tensile stress caused by external impact or continuous folding. The protection layer 190 can prevent glass powder from flying out when the cover glass 180 is broken by external impact or stress and glass powder is generated.

A coating layer 191 may be disposed on the protection layer 190 to protect the foldable display device 100 from external impact and scratches. For example, the coating layer 191 may include an organic material such as a urethane acrylic resin, a methacrylic resin, a silsesquioxane compound, or the like.

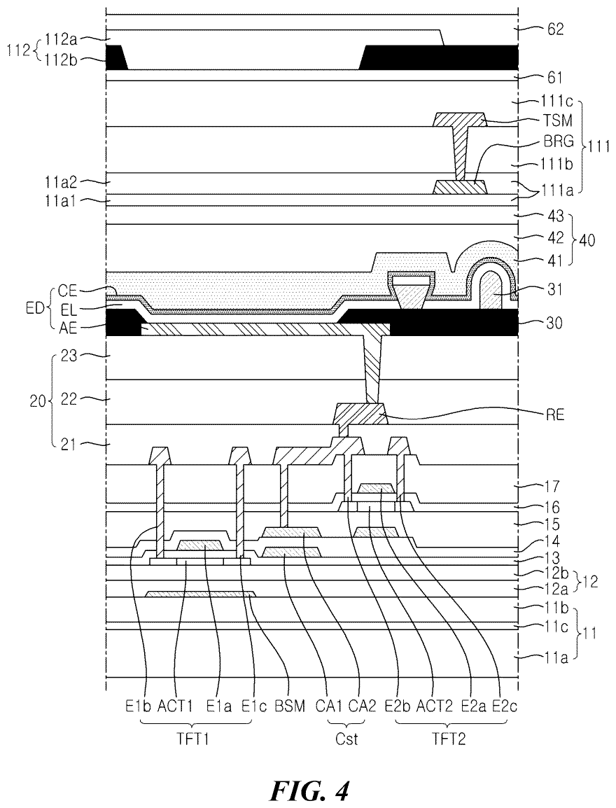

FIG. 4 is an example cross-sectional view taken along line B-B′ of the foldable display device 100 shown in FIG. 1.

Referring to FIG. 4, in one or more example embodiments, the display panel 110 may include a base plate 11, a transistor part, a light emitting element ED, a touch layer 111, and a color filter layer 112.

The base plate 11 may serve to support several components of the display panel 110 and include an insulating material such as a glass substrate or a plastic substrate.

The base plate 11 may include two or more layers. For example, the base plate 11 may include a first base plate 11a, a second base plate 11b, and an insulating layer 11c disposed between the first base plate 11a and the second base plate 11b.

The first base plate 11a and the second base plate 11b may include polyimide (PI). Polyimide (PI) may be a polymer with a relatively low crystallinity or mostly amorphous structure, be easily synthesized to form a thin film, and have advantages of good transparency, heat resistance, and mechanical properties. However, since the polyimide (PI) has poor moisture resistance, the moisture resistance of the first base plate 11a can be improved by disposing an insulating layer 11c including an inorganic insulating material such as silicon nitride (SiNx), silicon oxide (SiOx), and the like between the first base plate 11a and the second base plate 11b.

The transistor part may include insulating layers (such as a first buffer layer 12, a first gate insulating layer 13, a first interlayer insulating layer 14, a second buffer layer 15, a second gate insulating layer 16, and a second interlayer insulating layer 17), a first transistor TFT1, a second transistor TFT2, a storage capacitor Cst, and several electrodes or signal lines, which are disposed on the base plate 11.

The first transistor TFT1 may include a first active layer ACT1, a first gate electrode E1a, a first source electrode E1b, and a first drain electrode E1c. For example, the first active layer ACT1 may be a semiconductor layer including an oxide semiconductor, amorphous silicon, polysilicon, or low-temperature polysilicon (LTPS). For example, the first transistor TFT1 may be a p-channel transistor or an n-channel transistor, but aspects of the present disclosure are not limited thereto.

The second transistor TFT2 may include a second active layer ACT2, a second gate electrode E2a, a second source electrode E2b, and a second drain electrode E2c. For example, the second active layer ACT2 may be a semiconductor layer including an oxide semiconductor, amorphous silicon, polysilicon, or low-temperature polysilicon (LTPS). For example, the second transistor TFT2 may be a p-channel transistor or an n-channel transistor, but aspects of the present disclosure are not limited thereto.

Semiconductor materials of each of the first active layer ACT1 of the first transistor TFT1 and the second active layer ACT2 of the second transistor TFT2 may be as follows.

For example, the first active layer ACT1 of the first transistor TFT1 and the second active layer ACT2 of the second transistor TFT2 may include an oxide semiconductor material. In another example, the first active layer ACT1 of the first transistor TFT1 and the second active layer ACT2 of the second transistor TFT2 may include a low-temperature polysilicon semiconductor material. In another example, the first active layer ACT1 of the first transistor TFT1 may include a low-temperature polysilicon semiconductor material, and the second active layer ACT2 of the second transistor TFT2 may include an oxide semiconductor material. In another example, the first active layer ACT1 of the first transistor TFT1 may include an oxide semiconductor material, and the second active layer ACT2 of the second transistor TFT2 may include a low-temperature polysilicon semiconductor material.

The second active layer ACT2 of the second transistor TFT2 may be located higher from the base plate 11 than the first active layer ACT1 of the first transistor TFT1 in the cross-sectional view.

A first buffer layer 12 may be located under the first active layer ACT1 of the first transistor TFT1, and a second buffer layer 15 may be located under the second active layer ACT2 of the second transistor TFT2. For example, the first active layer ACT1 of the first transistor TFT1 may be located on the first buffer layer 12, and the second active layer ACT2 of the second transistor TFT2 may be located on the second buffer layer 15. The second buffer layer 15 may be located higher than the first buffer layer 12 in the cross-sectional view.

The storage capacitor Cst may be configured to maintain a constant voltage during one frame, and include elements or portions of several metal layers within the display panel 110. For example, the storage capacitor Cst may include a first capacitor electrode CA1 and a second capacitor electrode CA2.

The light emitting element ED may be disposed on a planarization layer 20. For example, the light emitting element ED may include a first electrode AE, which is an anode electrode, a second electrode CE, which is a cathode electrode, and an emission layer EL, which is disposed between the first electrode AE and the second electrode CE.

An encapsulation layer 40 may be disposed on the light emitting element ED. The encapsulation layer 40 may cover the light emitting element ED, and thereby, can protect the light emitting element ED from external moisture, oxygen, impact, and the like. For example, the encapsulation layer 40 may include a first encapsulation layer 41, a second encapsulation layer 42, and a third encapsulation layer 43.

The first encapsulation layer 41 may include an inorganic material capable of being deposited at a low temperature, such as silicon nitride (SiNx), silicon oxide (SiOx), silicon oxynitride (SiON), aluminum oxide (Al2O3), or the like. When the first encapsulation layer 41 is deposited in a low temperature atmosphere, the first encapsulation layer 41 can prevent the emission layer EL, which includes an organic material vulnerable to a high-temperature atmosphere during the deposition process, from being damaged.

The second encapsulation layer 42 may be disposed on the first encapsulation layer 41. For example, the second encapsulation layer 42 may include an organic insulating material such as an acrylic resin, an epoxy resin, a polyimide, a polyethylene, a silicon oxycarbon (SiOC), or the like. Since the second encapsulation layer 42 includes an organic material, the second encapsulation layer 42 can encapsulate elements disposed thereunder and also alleviate or reduce a step difference.

The third encapsulation layer 43 may be disposed on the second encapsulation layer 42. For example, the third encapsulation layer 43 may include an inorganic material such as silicon nitride (SiNx), silicon oxide (SiOx), silicon oxynitride (SiON), aluminum oxide (Al2O3), or the like.

According to these configurations, since the encapsulation layer 40 includes the multiple layers, the penetration of moisture or oxygen from the outside can be minimized, and thereby, the light emitting element ED can be effectively protected.

Hereinafter, the stack-up configuration or vertical structure of the display panel 110 is described in more detail with reference to FIG. 4.

Referring to FIG. 4, the first buffer layer 12 may be disposed on the base plate 11. For example, the first buffer layer 12 may be a single layer or a multilayer, but aspects of the present disclosure are not limited thereto. In the example where the first buffer layer 12 is a multilayer, the first buffer layer 12 may include a multi-buffer layer 12a and an active buffer layer 12b.

The multi-buffer layer 12a may be intended to block moisture and oxygen flowing into the base plate 11, and may include an inorganic material such as silicon nitride (SiNx), silicon oxide (SiOx), silicon oxynitride (SiON), aluminum oxide (Al2O3), or the like.

The active buffer layer 12b may be disposed on the multi-buffer layer 12a. The active buffer layer 12b may include an inorganic material such as silicon nitride (SiNx), silicon oxide (SiOx), silicon oxynitride (SiON), aluminum oxide (Al2O3), or the like. FIG. 4 illustrates that the active buffer layer 12b is in the form of one layer, but the active buffer layer 12b may be in the form of two or more layers.

The first active layer ACT1 of the first transistor TFT1 may be disposed on the first buffer layer 12. The first active layer ACT1 may include a channel region in which a channel is formed, a source connection region on one side of the channel region, and a drain connection region on the other side of the channel region.

A first gate insulating layer 13 may be disposed on the first active layer ACT1 of the first transistor TFT1. For example, the first gate electrode Ela of the first transistor TFT1 may be disposed on the first gate insulating layer 13. A first interlayer insulating layer 14 may be disposed on the first gate electrode Ela of the first transistor TFT1. The first gate electrode Ela of the first transistor TFT1 may be referred to as a first gate metal layer.

The second buffer layer 15 may be disposed on the first interlayer insulating layer 14.

The second active layer ACT2 of the second transistor TFT2 may be disposed on the second buffer layer 15. The second active layer ACT2 may include a channel region in which a channel is formed, a source connection region on one side of the channel region, and a drain connection region on the other side of the channel region.

A second gate insulating layer 16 may be disposed on the second active layer ACT2 of the second transistor TFT2. For example, the second gate electrode E2a of the second transistor TFT2 may be disposed on the second gate insulating layer 16. A second interlayer insulating layer 17 may be disposed on the second gate electrode E2a of the second transistor TFT2. The second gate electrode E2a of the second transistor TFT2 may be referred to as a second gate metal layer.

The first source electrode E1b and the first drain electrode E1c of the first transistor TFT1 and the second source electrode E2b and the second drain electrode E2c of the second transistor TFT2 may be disposed on the second interlayer insulating layer 17.

The first source electrode E1b and the first drain electrode E1c of the first transistor TFT1 may be connected to the source connection region and the drain connection region of the first active layer ACT1, respectively, through holes of the second interlayer insulating layer 17, the second gate insulating layer 16, the second buffer layer 15, the first interlayer insulating layer 14, and the first gate insulating layer 13.

The second source electrode E2b and the second drain electrode E2c of the second transistor TFT2 may be connected to the source connection region and the drain connection region of the second active layer ACT2, respectively, through holes of the second interlayer insulating layer 17 and the second gate insulating layer 16.

The first source electrode E1b and the first drain electrode E1c of the first transistor TFT1, and the second source electrode E2b and the second drain electrode E2c of the second transistor TFT2 may include a first source-drain metal and may be disposed in a first source-drain metal layer.

The storage capacitor Cst may be formed by a first capacitor electrode CA1 and a second capacitor electrode CA2. In one or more aspects, the storage capacitor Cst may be formed by three or more capacitor electrodes, and may be in the form of two or more capacitors connected in parallel.

Each of the first capacitor electrode CA1 and the second capacitor electrode CA2 may be disposed in several metal layers disposed within the display panel 110. For example, the first capacitor electrode CA1 may include the same first gate metal as the first gate electrode Ela on the first gate insulating layer 13 and may be disposed in the first gate metal layer. The second capacitor electrode CA2 may be disposed on the first interlayer insulating layer 14.

The second source electrode E2b of the second transistor TFT2 may be electrically connected to the second capacitor electrode CA2 through holes of the second interlayer insulating layer 17, the second gate insulating layer 16, and the second buffer layer 15.

The transistor part may further include a light shielding layer BSM disposed on the base plate 11. The light shielding layer BSM may be overlapped with the first active layer ACT1 of the first transistor TFT1 to prevent light from the outside from entering the first transistor TFT1. The light shielding layer BSM may be disposed under the first active layer ACT1 of the first transistor TFT1. For example, the light shielding layer BSM may be disposed between the base plate 11 and the first buffer layer 12.

The planarization layer 20 may be disposed on the first transistor TFT1 and the second transistor TFT2. For example, the planarization layer 20 may be an organic insulating layer including an organic insulating material, and be disposed between the second interlayer insulating layer 17 and the light emitting element ED.

The planarization layer 20 may include a first planarization layer 21, a second planarization layer 22, and a protection layer 111c. FIG. 4 illustrates that the planarization layer 20 includes three layers, but aspects of the present disclosure are not limited thereto.

The first planarization layer 21 may be disposed on the first source electrode E1b and the first drain electrode E1c of the first transistor TFT1, and the second source electrode E2b and the second drain electrode E2c of the second transistor TFT2. For example, the first planarization layer 21 may be disposed on the second interlayer insulating layer 17 while covering both the first transistor TFT1 and the second transistor TFT2.

A connection electrode RE may be disposed on the first planarization layer 21. The connection electrode RE may electrically interconnect the second source electrode E2b of the second transistor TFT2 and a first electrode AE.

The connection electrode RE may be electrically connected to the second source electrode E2b of the second transistor TFT2 through a hole of the first planarization layer 21. The second source electrode E2b of the second transistor TFT2 may be electrically connected to the second capacitor electrode CA2 of the storage capacitor Cst.

The connection electrode RE may be disposed in the second source-drain metal layer on the first planarization layer 21 and may include a second source-drain metal.

The second planarization layer 22 may be disposed on the connection electrode RE. For example, the second planarization layer 22 may be disposed on the first planarization layer 21 while covering the whole connection electrode RE.

The third planarization layer 23 may be disposed on the second planarization layer 22.

The light emitting element ED may be disposed on the third planarization layer 23. The light emitting element ED may include a first electrode AE, a second electrode CE, and a emission layer EL disposed between the first electrode AE and the second electrode CE. A light emitting area of the light emitting element ED may be formed by an area where the first electrode AE, the emission layer EL, and the second electrode CE overlap with, and contact, each other.

The first electrode AE may be disposed on the third planarization layer 23. The first electrode AE may be electrically connected to the connection electrode RE through holes of the third planarization layer 23 and the second planarization layer 22.

A bank 30 may be disposed on the first electrode AE to define pixels. An opening of the bank 30 may expose a portion of the first electrode AE to form a light emitting area. The opening of the bank 30 may overlap with the portion of the first electrode AE.

For example, the bank 30 may include a material including a black pigment, or an organic material including a benzocyclobutene resin, a polyimide resin, an acrylic resin, a photosensitive polymer, or the like, but aspects of the present disclosure are not limited thereto. In the example where the bank 30 includes a material including a black pigment or a black dye, this bank 30 may be a black bank. When the bank 30 includes a material including a black pigment or a black dye, light from the outside or light reflected from the outside can be blocked, and thereby, the luminance of the foldable display device 100 can be further improved.

The bank 30 may further include a spacer 31 disposed in an upper portion of the bank 30 to prevent damage that may occur when a deposition mask used during forming the emission layer EL contacts the bank 30, and to maintain a certain distance between the bank 30 and the deposition mask.

The emission layer EL of the light emitting element ED may be disposed on a portion of the first electrode AE and the bank 30. The second electrode CE may be disposed on the emission layer EL.

The encapsulation layer 40 may be disposed on the second electrode CE of the light emitting element ED. For example, the encapsulation layer 40 may prevent moisture or oxygen from penetrating into the light emitting element ED. For example, the encapsulation layer 40 may prevent moisture or oxygen from penetrating into an organic material included in the emission layer EL of the light emitting element ED. FIG. 4 illustrates that the encapsulation layer 40 is a multilayer including a first encapsulation layer 41, a second encapsulation layer 42, and a third encapsulation layer 43, but aspects of the present disclosure are not limited thereto.

In one or more aspects, the display panel 110 may further include the touch layer 111 and the color filter layer 112.

The touch layer 111 may include a touch buffer layer 111a, a touch insulation layer 111b, a touch electrode including a touch sensor metal TSM and a bridge metal BRG, and a protection layer 111c.

The touch buffer layer 111a may be disposed on the encapsulation layer 40. For example, the touch buffer layer 111a may include a first touch buffer layer 11al disposed on the third encapsulation layer 43, and a second touch buffer layer 11a2 covering the bridge metal BRG on the first touch buffer layer 11al.

Each bridge metal BRG may be disposed on the first touch buffer layer 11al to electrically interconnect a plurality of touch sensor metals TSMs.

The touch insulation layer 111b may be disposed on the second touch buffer layer 11a2, and one or more touch sensor metals TSM connected to at least one bridge metal BRG may be disposed on the touch insulation layer 111b. For example, the one or more touch sensor metals TSM may be connected to the at least one bridge metal BRG through holes formed in the touch insulation layer 111b and the second touch buffer layer 11a2.

The one or more touch sensor metals TSM may be covered by the protection layer 111c disposed on the touch insulation layer 111b. Accordingly, elements or patterns disposed underneath the protection layer 111c can be protected by the protection layer 111c, and a difference in height of configurations caused by these elements or patterns can be alleviated or reduced. For example, the protection layer 111c may include an organic material such as an acrylic resin, an epoxy resin, a phenolic resin, a polyamide resin, a polyimide resin, or the like. However, the material of the protection layer 111c is not limited thereto, and for example, may include at least one inorganic material and at least one organic material.

The color filter layer 112 may include a color filter pattern 112a and a black matrix 112b. For example, a color filter buffer layer 61 may be disposed on the touch layer 111, and the color filter layer 112 may be formed on the color filter buffer layer 61.

The color filter pattern 112a may be located to correspond to a pixel area, and be formed by patterning a phase change ink using an inkjet device. For example, a red color filter pattern including a red pigment may be formed at an area corresponding to a pixel area where an organic emission layer emitting red light is formed, a green color filter pattern including a green pigment may be formed at an area corresponding to a pixel area where an organic emission layer emitting green light is formed, and a blue color filter pattern including a blue pigment may be formed at an area corresponding to a pixel area where an organic emission layer emitting blue light is formed.

The black matrix 112b may be formed to prevent light leakage and overlap with an edge of the color filter pattern 112a. For example, the black matrix 112b may be formed along a pattern of the bank 30. For example, the black matrix 112b may have openings similar to openings of the bank 30, and each of color filter patterns 112a may be disposed in a respective one of the openings of the black matrix 112b. According to these configurations, since the black matrix 112b is disposed between the color filter patterns 112a, external light can be absorbed. For example, the black matrix 112b may include a material such as carbon black, a black resin, black ink, a pigment absorbing visible light, or the like.

The color filter pattern 112a and the black matrix 112b may be covered by a color filter protection layer 62. Accordingly, a difference in height caused by the color filter pattern 112a and the black matrix 112b can be alleviated or reduced, and the color filter pattern 112a and the black matrix 112b can be protected from external undesired substances or impact.

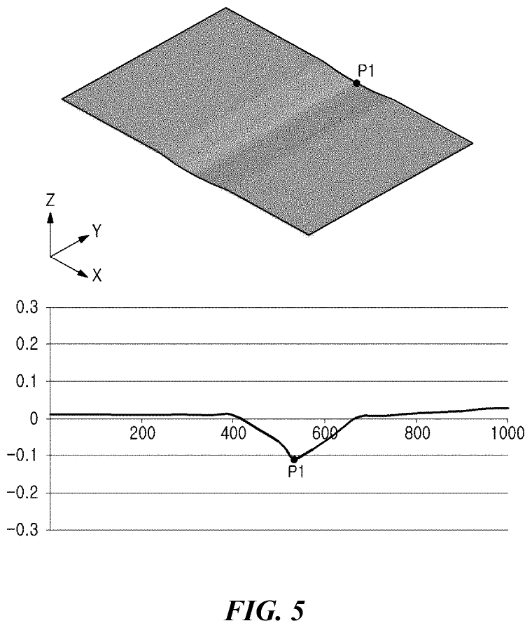

FIG. 5 illustrates a change of a wrinkle of the foldable display device 100 including the first adhesive layer 130 having a modulus of 0.05 Mpa.

FIG. 5 shows a change of a wrinkle (curvature) when the first adhesive layer 130 disposed under, or underneath, the display panel 110 has a modulus of 0.05 MPa at room temperature and is folded and unfolded for 1 hour. As shown in the experimental results, when the first adhesive layer 130 is formed to have a low modulus of 0.05 MPa at room temperature, a slope of a wrinkle at the lowest position P1 in the folding area FA was measured to be approximately 19 μm/mm.

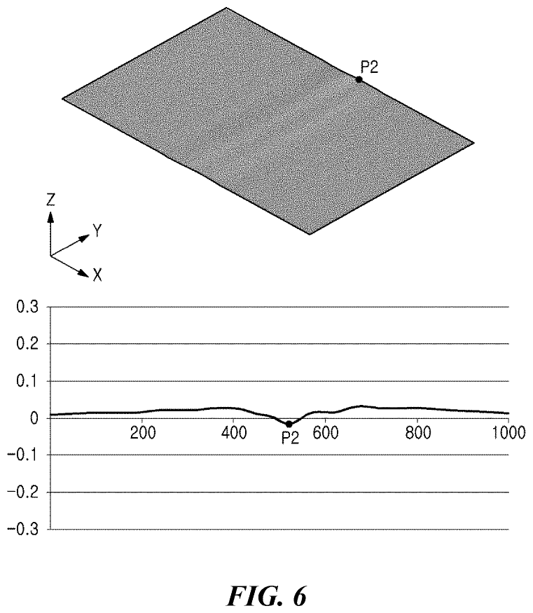

FIG. 6 illustrates a change of a wrinkle of the foldable display device 100 including the first adhesive layer 130 having a modulus of 1 Mpa.

FIG. 6 shows a change of a wrinkle (curvature) when the first adhesive layer 130 disposed under, or underneath, the display panel 110 has a modulus of 1 MPa at room temperature and is folded and unfolded for 1 hour. As shown in the experimental results, when the first adhesive layer 130 is formed to have a high modulus of 1 MPa at room temperature, a slope of the wrinkle at the lowest position P2 in the folding area FA was measured to be about 9 μm/mm.

Referring to FIG. 5 and FIG. 6, it can be seen that the depth of the wrinkle in the folding area FA is smaller when the first adhesive layer 130 has a high modulus of 1 MPa or more. Therefore, when the modulus of the first adhesive layer 130 is provided to be 1 MPa or more, the deformation in the folding area FA can be reduced. Since a degree of the deformation in this folding area FA indicates a degree of the formation of the wrinkle, when the first adhesive layer 130 has a high modulus of 1 MPa or more, wrinkles visible on the display panel 110 can be reduced or improved, and thereby, the appearance quality of the display panel 110 can be improved.

The examples, aspects, and embodiments described above will be briefly described as follows.

According to the one or more example embodiments described herein, a foldable display device can be provided that includes a display panel including a folding area being bendable or foldable with respect to a folding axis and a non-folding area, a support layer disposed on a back surface of the display panel, a first adhesive layer disposed between the display panel and the support layer, a base substrate disposed on a back surface of the support layer and having an open pattern formed in an area overlapping with the folding area, and a second adhesive layer disposed between the support layer and the base substrate. In one or more aspects, the first adhesive layer may have a modulus greater than the second adhesive layer.

In one or more aspects, the first adhesive layer may have a modulus 40 to 60 times as high as that of the second adhesive layer.

In one or more aspects, the first adhesive layer may have a modulus of 1 MPa or more.

In one or more aspects, the second adhesive layer may have a modulus of 0.02 to 0.07 MPa.

In one or more aspects, the first adhesive layer and the second adhesive layer may include a pressure sensitive adhesive (PSA) or an optical clear adhesive (OCA).

In one or more aspects, wherein the support layer may include a first support layer disposed on a back surface of the first adhesive layer.

In one or more aspects, the support layer may further include an intermediate adhesive layer disposed on a back surface of the first support layer, and a second support layer disposed on a back surface of the intermediate adhesive layer.

In one or more aspects, the foldable display device may further include a third adhesive layer disposed on the display panel, a polarizing plate disposed on the third adhesive layer, a fourth adhesive layer disposed on the polarizing plate, a cover glass disposed on the fourth adhesive layer, a fifth adhesive layer disposed on the cover glass, and a protection layer disposed on the fifth adhesive layer.

In one or more aspects, the third adhesive layer, the fourth adhesive layer, and the fifth adhesive layer may include an optical clear adhesive (OCA).

In one or more aspects, the first adhesive layer may include a plurality of grooves patterned on one surface of the first adhesive layer facing the display panel, and the plurality of grooves may be formed to extend in a folding axis direction.

In one or more aspects, the plurality of grooves may be disposed to overlap with the folding area.

In one or more aspects, the plurality of grooves may be disposed in the folding area and a portion of the non-folding area adjacent to the folding area.

In one or more aspects, the plurality of grooves may include a plurality of first patterns disposed to be spaced apart from each other in the folding axis direction, and a plurality of second patterns disposed to be spaced apart from each other in the folding axis direction and disposed to be spaced apart from the plurality of first patterns in a direction perpendicular to the folding axis.

In one or more aspects, the plurality of first patterns and the plurality of second patterns may be disposed in a plurality of lines in the direction perpendicular to the folding axis, and both ends of each of the plurality of second patterns are disposed not to align with both ends of each of the plurality of first patterns.

According to the one or more example embodiments described herein, a foldable display device can be provided that includes a display panel including a folding area being bendable or foldable with respect to a folding axis and a non-folding area, a support layer disposed on a back surface of the display panel, a first adhesive layer disposed between the display panel and the support layer, a base substrate disposed on a back surface of the support layer and having an open pattern formed in an area overlapping with the folding area, and a second adhesive layer disposed between the support layer and the base substrate. In one or more aspects, the first adhesive layer may have a modulus greater than the second adhesive layer, and a plurality of grooves extending in a folding axis direction are patterned on one side of the first adhesive layer facing the display panel.

In one or more aspects, the first adhesive layer may have a modulus 40 to 60 times as high as that of the second adhesive layer.

In one or more aspects, the support layer may include a first support layer disposed on a back surface of the first adhesive layer, an intermediate adhesive layer disposed on a back surface of the first support layer, and a second support layer disposed on a back surface of the intermediate adhesive layer.

In one or more aspects, the foldable display device may further include a third adhesive layer disposed on the display panel, a cover glass disposed on the fourth adhesive layer, a fifth adhesive layer disposed on the cover glass, and a protection layer disposed on the fifth adhesive layer.

In one or more aspects, the plurality of grooves may be disposed in the folding area and a portion of the non-folding area adjacent to the folding area.

In one or more aspects, the plurality of grooves may include a plurality of first patterns disposed to be spaced apart from each other in the folding axis direction, and a plurality of second patterns disposed to be spaced apart from each other in the folding axis direction and disposed to be spaced apart from the plurality of first patterns in a direction perpendicular to the folding axis.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

### DESCRIPTION OF THE REFERENCE NUMERALS

100: foldable display device
110: display panel
120: support layer
130: first adhesive layer
140: base substrate
150: second adhesive layer
161: third adhesive layer
162: fourth adhesive layer
163: fifth adhesive layer
170: polarizing plate
180: cover glass
190: protection layer

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A foldable display device comprising:
a display panel comprising a folding area and a non-folding area, the folding area being bendable or foldable with respect to a folding axis;
a support layer disposed on a back surface of the display panel;
a first adhesive layer disposed between the display panel and the support layer;
a base substrate disposed on a back surface of the support layer and having an open pattern in an area of the base substrate overlapping with the folding area; and
a second adhesive layer disposed between the support layer and the base substrate,
wherein the first adhesive layer has a modulus greater than a modulus of the second adhesive layer.

2. The foldable display device of claim 1, wherein the first adhesive layer has a modulus 40 to 60 times as high as the modulus of the second adhesive layer.

3. The foldable display device of claim 1, wherein the modulus of the first adhesive layer is 1 MPa or more.

4. The foldable display device of claim 1, wherein the modulus of the second adhesive layer is 0.02 to 0.07 MPa.

5. The foldable display device of claim 1, wherein the first adhesive layer and the second adhesive layer comprise a pressure sensitive adhesive or an optical clear adhesive.

6. The foldable display device of claim 1, wherein the support layer comprises a first support layer disposed on a back surface of the first adhesive layer.

7. The foldable display device of claim 6, wherein the support layer further comprises an intermediate adhesive layer disposed on a back surface of the first support layer, and a second support layer disposed on a back surface of the intermediate adhesive layer.

8. The foldable display device of claim 1, further comprising:
a third adhesive layer disposed on the display panel;
a polarizing plate disposed on the third adhesive layer;
a fourth adhesive layer disposed on the polarizing plate;
a cover glass disposed on the fourth adhesive layer;
a fifth adhesive layer disposed on the cover glass; and
a protection layer disposed on the fifth adhesive layer.

9. The foldable display device of claim 8, wherein the third adhesive layer, the fourth adhesive layer, and the fifth adhesive layer comprise an optical clear adhesive.

10. The foldable display device of claim 1, wherein the first adhesive layer comprises a plurality of grooves on one surface of the first adhesive layer facing the display panel, and the plurality of grooves extend in a folding axis direction.

11. The foldable display device of claim 10, wherein the plurality of grooves are disposed to overlap with the folding area.

12. The foldable display device of claim 10, wherein the plurality of grooves are disposed in the folding area and a portion of the non-folding area adjacent to the folding area.

13. The foldable display device of claim 10, wherein the plurality of grooves comprise a plurality of first patterns disposed to be spaced apart from each other in the folding axis direction, and a plurality of second patterns disposed to be spaced apart from each other in the folding axis direction and disposed to be spaced apart from the plurality of first patterns in a direction perpendicular to the folding axis.

14. The foldable display device of claim 13, wherein the plurality of first patterns and the plurality of second patterns are disposed in a plurality of lines in the direction perpendicular to the folding axis, and both ends of each of the plurality of second patterns are disposed not to align with both ends of each of the plurality of first patterns in the direction perpendicular to the folding axis.

15. The foldable display device of claim 1, further comprising:
at least one additional adhesive layer for attaching additional layers of the foldable display device,
wherein the modulus of the first adhesive layer is greater than a modulus of the at least one additional adhesive layer.

16. The foldable display device of claim 15,
wherein the modulus of the second adhesive layer and the modulus of the at least one additional adhesive layer are of the same magnitude.

17. A foldable display device comprising:
a display panel comprising a folding area and a non-folding area, the folding area being bendable or foldable with respect to a folding axis;
a support layer disposed on a back surface of the display panel;
a first adhesive layer disposed between the display panel and the support layer;
a base substrate disposed on a back surface of the support layer and having an open pattern in an area of the base substrate overlapping with the folding area;
a second adhesive layer disposed between the support layer and the base substrate; and
a plurality of grooves extending in a folding axis direction on one side of the first adhesive layer facing the display panel,
wherein the first adhesive layer has a modulus greater than a modulus of the second adhesive layer.

18. The foldable display device of claim 17, wherein the support layer comprises:
a first support layer disposed on a back surface of the first adhesive layer;
an intermediate adhesive layer disposed on a back surface of the first support layer; and
a second support layer disposed on a back surface of the intermediate adhesive layer.

19. The foldable display device of claim 17, further comprising:
a third adhesive layer disposed on the display panel;
a polarizing plate disposed on the third adhesive layer;
a fourth adhesive layer disposed on the polarizing plate;
a cover glass disposed on the fourth adhesive layer,
a fifth adhesive layer disposed on the cover glass; and
a protection layer disposed on the fifth adhesive layer.

20. The foldable display device of claim 17, wherein the plurality of grooves comprise a plurality of first patterns disposed to be spaced apart from each other in the folding axis direction, and a plurality of second patterns disposed to be spaced apart from each other in the folding axis direction and disposed to be spaced apart from the plurality of first patterns in a direction perpendicular to the folding axis.
